(19) United States
(12) Patent Application Publication
(10) Pub. No.: US 2007/0040246 A1
(43) Pub. Date: Feb. 22, 2007

(54) Touch pad module with electrostatic discharge protection

(76) Inventors: I-Tai Chen, Hsinchuang City (TW); Ming-Te Lin, Shulin City (TW)

Correspondence Address: RABIN & BERDO, P.C., Suite 500, 1101 14th Street, N.W., Washington, DC, 20005, US

(21) Appl. No.: 11/330,106

(22) Filed: Jan. 12, 2006

(30) Foreign Application Priority Data
Aug. 18, 2005 (TW) 94214172

(51) Int. Cl. H01L 23/495

(52) U.S. Cl. 257/666

(57) ABSTRACT

A touch pad module with electrostatic discharge protection is disclosed. The touch pad module comprises a casing, a metal sheet, a touch pad and a metal holder, wherein the casing covers the metal sheet and has a first opening to expose a portion of the touch pad. The metal sheet is disposed on the touch pad and has a second opening corresponding to the first opening. The extension of the metal sheet contacts the metal holder and the metal holder is disposed under the touch pad.

### RELATED APPLICATIONS

The present application is based on, and claims priority from, Taiwan Application Serial Number 94214172, filed Aug. 18, 2005, the disclosure of which is hereby incorporated by reference herein in its entirety.

### FIELD OF THE INVENTION

The present invention relates to a touch pad module, and more particularly, to a touch pad module with electrostatic discharge protection.

### BACKGROUND OF THE INVENTION

With advances in technology, electronic products are becoming more and more popular to the general public. In order to make many different users good at using these products without much learning, the interface design between the products and the users should be simple and easy to use. Therefore, designs of input devices are becoming more and more convenient to meet the needs of the users. One kind of input device is the touch pad, which is very simple, convenient and applied in various electronic products, such as notebook computers and personal digital assistants (PDA).

Any kind of electronic product requires electrostatic discharge protection so as to prevent components of the electronic product from damage, including the touch pad. Thus, the touch pad also has to be designed to incorporate electrostatic discharge protection in its structure.

FIG. 1 is a schematic exploded view showing a conventional touch pad module with electrostatic discharge protection. The structure of the touch pad module includes a casing 10, a touch pad 20, a conductive foam 30, and a metal holder 40. Herein, the casing 10 has an opening 12 to expose a portion of the touch pad 20 under the casing 10. The metal holder 40 is disposed under the touch pad 20 and fixes the touch pad 20. The conductive foam 30 is disposed between the touch pad 20 and the metal holder 40 and makes the touch pad 20 electrically contact the metal holder 40. When electrostatic charge is produced on the touch pad 20, it firstly passes through the touch pad 20 and then is transmitted to the conductive foam 30. Finally, the electrostatic charge passes through the metal holder 40 to discharge.

In general, the electrostatic charge on the touch pad 20 must pass through a long path on the touch pad 20 to the conductive foam 30 since the conductive foam 30 is disposed under the touch pad 20. Thus, the effect of discharging the electrostatic charge in the conventional structure is not ideal.

### SUMMARY OF THE INVENTION

Accordingly, an improved touch pad module is needed to solve the problem of discharging the electrostatic charge on the touch pad incompletely and to achieve the object of discharging the electrostatic charge effectively in the touch pad module.

One aspect of the present invention is to provide a touch pad module with electrostatic discharge protection to eliminate the accumulation of the electrostatic charge on the surface of the touch pad substantially and discharge the electrostatic charge on the surface of the touch pad by means of applying the metal sheet to directly contact the touch pad.

Another aspect of the present invention is to provide a touch pad module with electrostatic discharge protection to discharge the electrostatic charge on the surface of the touch pad by means of applying the metal sheet to contact the touch pad and the button. At the same time, the metal sheet can serve as a dome of the button.

To achieve the aforementioned aspects, the present invention provides a touch pad module with electrostatic discharge protection. The touch pad module comprises a casing, a metal sheet, a touch pad and a metal holder, wherein the casing covers the metal sheet and has a first opening to expose a portion of the touch pad. The metal sheet is disposed on the touch pad and has a second opening corresponding to the first opening. An extension of the metal sheet contacts the metal holder and the metal holder is disposed under the touch pad.

According to the embodiment of the present invention, the material of the above-mentioned metal sheet is such as aluminum, iron or stainless steel.

According to the embodiment of the present invention, the surroundings of the above-mentioned metal sheet and its extension can contact other metallic parts.

With the application of the touch pad module with electrostatic discharge protection of the present invention, the metal sheet directly installed on the touch pad can effectively and completely discharge the electrostatic charge as compared with the conventional structures.

### BRIEF DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 is a schematic exploded view showing a conventional touch pad module with electrostatic discharge protection;

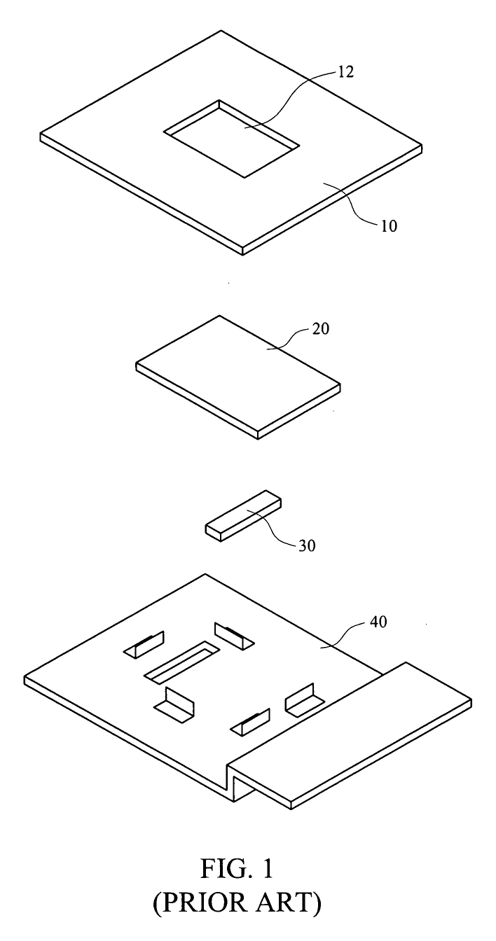

FIG. 2 is a schematic exploded view showing the first preferred embodiment of the present invention; and

FIG. 3 is a schematic exploded view showing the second preferred embodiment of the present invention.

### DETAILED DESCRIPTION OF THE PREFERRED EMBODIMENT

A touch pad module with electrostatic discharge protection is disclosed. The touch pad module comprises a casing, a metal sheet, a touch pad and a metal holder, wherein the casing covers the metal sheet and has a first opening to expose a portion of the touch pad. The metal sheet is disposed on the touch pad and has a second opening corresponding to the first opening. An extension of the metal sheet contacts the metal holder and the metal holder is disposed under the touch pad.

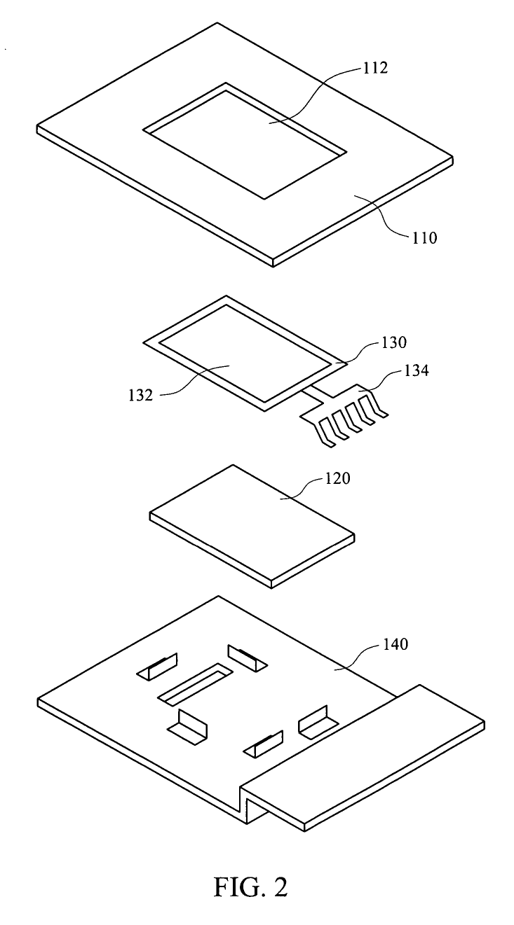

Reference is made to FIG. 2, which is a schematic exploded view showing the first preferred embodiment of the present invention. The structure of the touch pad module includes a casing 110, a touch pad 120, a metal sheet 130 and a metal holder 140. Herein, the casing 110, such as the upper cover or casing of a notebook computer or PDA, is disposed on the metal sheet 130 and has a first opening 112 to expose a portion of the touch pad 120 under the casing 110. The metal sheet 130 is disposed between the touch pad 120 and the casing 110 and has a second opening 132 to expose a portion of the touch pad 120 under the metal sheet 130. It is appreciated that the first opening 112 of the casing 110 corresponds to the second opening 132 of the meal sheet 130. In the embodiment, one side of the metal sheet 130 has an extension, such as a conductive paw 134, to contact the metal holder 140. The conductive paw 134 is directly formed on the side of the metal sheet 130 by metal stamping/punching method. In other words, the conductive paw 134 and the metal sheet 130 are formed together. Without limitation, any shape of the metal parts formed in any place of the surroundings of the metal sheet 130 by using any kind of method can be applied in the present invention. In the embodiment, the material of the metal sheet 130 is such as aluminum, iron or stainless steel. The metal holder 140 is disposed under the touch pad 120 and can fix the touch pad 120. In the embodiment, the metal holder 140 is a metal frame. Without limitation, any shape of the metal parts can be applied as the metal holder 140 in the present invention.

The casing 110 and the metal holder 140 can protect and fix the touch pad 120 and the metal sheet 130. Since the metal sheet 130 is disposed on the touch pad 120 and directly contacting the surface of the touch pad 120, the electrostatic charge is directly transmitted to the nearby metal sheet 130 while the electrostatic charge is produced on the touch pad 120. The electrostatic charge passes through the conductive paw 134 of the metal sheet 130 to be transmitted to the metal holder 140 to discharge. Thus, the electrostatic charge does not destroy the component parts of the touch pad 120. According to the embodiment of the present invention, the metal sheet 130 shown in the FIG. 2 is directly disposed on the touch pad 120, so the electrostatic charge on the touch pad 120 is transmitted by the metal sheet 130 which is near the touch pad 120.

Thus, the effect of discharging the electrostatic charge in the present invention is better than that of the conventional structure that needs the conductive foam to transmit the electrostatic charge. Besides, in the embodiment, the metal sheet 130 and its extension (the conductive paw 134) can contact other metallic parts (not shown) to discharge the electrostatic charge completely.

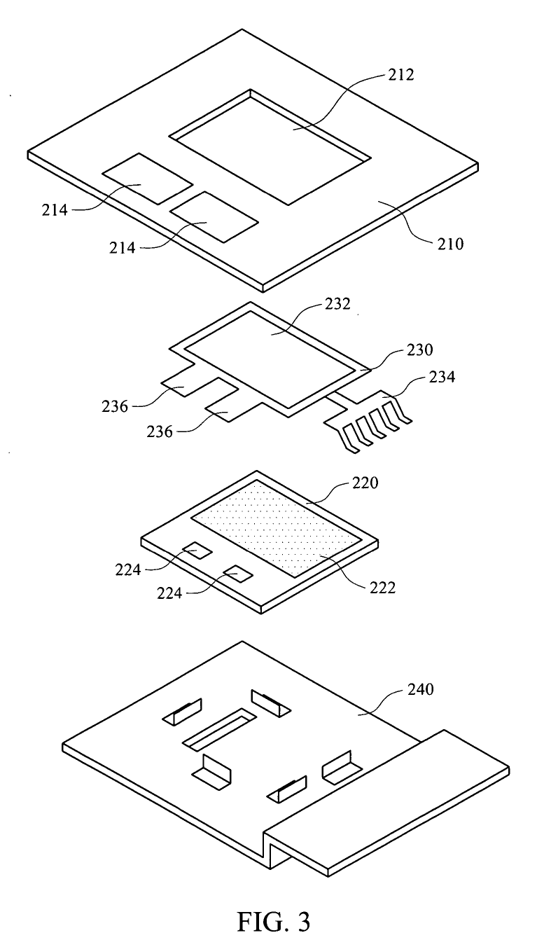

Reference is made to FIG. 3, which is a schematic exploded view showing the second preferred embodiment of the present invention. The structure of the touch pad module includes a casing 210, a touch pad 220, a metal sheet 230 and a metal holder 240. In the embodiment, the touch pad 220 is a printed circuit board where a touch element 222 and at least a switch element 224 are disposed. In the embodiment, two switch elements 224 are used to illustrate the invention. Without limitation, those skilled in the art can use another number of the switch elements in the present invention. The touch pad 220 has a transmission line (not shown) to contact the host. The casing 210, such as the upper cover or casing of a notebook computer or PDA, is disposed on the metal sheet 230 and has a first opening 212 to expose a portion of the touch element 222 on the touch pad 220 under the casing 210. Besides, the casing 210 has a button portion which corresponds to the two switch elements 224 on the touch pad 220. In the embodiment, the button portion includes two buttons 214. The metal sheet 230 is disposed between the touch element 222 on the touch pad 220 and the casing 210 and has a second opening 232 to expose a portion of the touch element 222 on the touch pad 220 under the metal sheet 230. It is appreciated that the metal sheet 230 can directly contact the touch element 222, and the first opening 212 of the casing 210 corresponds to the second opening 232 of the metal sheet 230. In the embodiment, one side of the metal sheet 230 has a first extension, such as a conductive paw 234, to contact the metal holder 240. The conductive paw 234 is directly formed on the side of the metal sheet 230 by a metal stamping/punching method. In other words, the conductive paw 234 and the metal sheet 230 are formed together. Without limitation, any shape of the metal parts formed in any place of the surroundings of the metal sheet 230 by using any kind of method can be applied in the present invention.

In addition, in the embodiment, the other side of the metal sheet 230 has a second extension, such as a metal dome 236, to cover the two switch elements 224 on the touch pad 220 under the metal sheet 230. Similarly, the method for forming the metal dome 236 is the same as that of the conductive paw 234. In the embodiment, the material of the metal sheet 230 is such as aluminum, iron or stainless steel. The metal holder 240 is disposed under the touch pad 220 and can fix the touch pad 220. In the embodiment, the metal holder 240 is a metal frame. Without limitation, any shape of the metal parts can be applied as the metal holder 240 in the present invention.

The casing 210 and the metal holder 240 can protect and fix the touch pad 220 and the metal sheet 230. Since the metal sheet 230 and its extension (the metal dome 236) can directly contact the touch element 222 on the touch pad 220 and the two buttons 214, the electrostatic charge is directly transmitted to the metal sheet 230 and the metal dome 236 near the touch element 222 and the two buttons 214 while the electrostatic charge is produced on the touch element 222 and the two buttons 214. The electrostatic charge then passes through the conductive paw 134 of the metal sheet 130 to be transmitted to the metal holder 140 to discharge. Thus, the electrostatic charge does not destroy the component parts of the touch pad 220. The position of the metal sheet 230 which is directly disposed on the touch pad 220 in the present invention is closer to the position where the electrostatic charge is produced as compared with the position of the conductive foam in the conventional structure, so the effect of discharging the electrostatic charge in the present invention is better than that of the conventional structure. Besides, in the embodiment, the metal sheet 230 and its extension (the conductive paw 134) can contact other metallic parts (not shown) to discharge the electrostatic charge completely. In the embodiment, the electrostatic charge on the touch element 222 and the two buttons 214 can be removed by using the metal sheet 230; and the metal dome 236 extended from one side of the metal sheet 230 can serve as a dome of the two buttons 214.

Accordingly, the characteristic structure of the touch pad module with electrostatic discharge protection disclosed in the present invention is the metal sheet directly contacting the surface of the touch pad to remove the electrostatic charge, so the structure of the present invention can effectively and completely remove the electrostatic charge as compared with the other conventional structure. Besides, the metal sheet not only protects the touch pad from being affected by the electrostatic charge, but also can extend the metal sheet to the button portion, i.e. the same metal sheet can remove the electrostatic charge on the touch pad and button at the same time. Moreover, the metal sheet can serve as a dome of the button. Therefore, the structure of the present invention can effectively and substantially remove the electrostatic charge as compared with the conventional structure.

According to the above-mentioned preferred embodiments, the advantage of the touch pad module in the present invention is that the object of protecting the touch pad from electrostatic charge can be achieved by disposing the metal sheet directly on the touch pad without adding the conductive foam. Therefore, the structure of the present invention can effectively and substantially remove the electrostatic charge as compared with the conventional structure.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A touch pad module with electrostatic discharge protection, comprising:
a metal holder;
a touch pad installed on said metal holder; and
a metal sheet disposed on said touch pad, wherein said metal sheet comprises a first extension used for contacting said metal holder, and said metal sheet has a first opening to expose a portion of said touch pad.

2. The touch pad module of claim 1, further comprising:
a casing covering said metal sheet, wherein said casing has a second opening which corresponds to said first opening.

3. The touch pad module of claim 1, further comprising:
a switch element installed on said touch pad.

4. The touch pad module of claim 3, wherein said metal sheet comprises a second extension which is disposed on said switch element.

5. The touch pad module of claim 4, wherein said second extension is a metal dome.

6. The touch pad module of claim 4, wherein said second extension and said metal sheet are formed together.

7. The touch pad module of claim 1, wherein said first extension is a conductive paw.

8. The touch pad module of claim 1, wherein said first extension and said metal sheet are formed together.

9. The touch pad module of claim 1, wherein said metal holder is a metal frame.

10. The touch pad module of claim 1, wherein the material of said metal sheet is aluminum.

11. The touch pad module of claim 1, wherein the material of said metal sheet is iron.

12. The touch pad module of claim 1, wherein the material of said metal sheet is stainless steel.

13. A touch pad module with electrostatic discharge protection, comprising:
a metal frame;
a touch pad installed on said metal frame, wherein a touch element and at least a switch element are disposed on said touch pad;
a metal sheet disposed on said touch element, wherein said metal sheet comprises a first extension and a second extension used for contacting said metal frame and covering said switch element respectively, and said metal sheet has a first opening to expose a portion of said touch element; and
a casing covering said metal sheet, wherein said casing has a second opening which corresponds to said first opening and a button portion which corresponds to said switch element.

14. The touch pad module of claim 13, wherein said first extension is a conductive paw.

15. The touch pad module of claim 13, wherein said second extension is a metal dome.

16. The touch pad module of claim 13, wherein said first extension and said metal sheet are formed together.

17. The touch pad module of claim 13, wherein said second extension and said metal sheet are formed together.

18. The touch pad module of claim 13, wherein the material of said metal sheet is aluminum.

19. The touch pad module of claim 13, wherein the material of said metal sheet is iron.

20. The touch pad module of claim 13, wherein the material of said metal sheet is stainless steel.
